(19) United States
(12) Patent Application Publication
(10) Pub. No.: US 2011/0012239 A1
(43) Pub. Date: Jan. 20, 2011

(54) Barrier Layer On Polymer Passivation For Integrated Circuit Packaging

(75) Inventors: Shiqun Gu, San Diego, CA (US); Urmi Ray, San Diego, CA (US); Yiming Li, San Diego, CA (US); Arvind Chandrasekaran, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/758,311

(22) Filed: Apr. 12, 2010

Related U.S. Application Data
(60) Provisional application No. 61/226,689, filed on Jul. 17, 2009.

(51) Int. Cl. H01L 29/06; H01L 21/768; H01L 21/311

(52) U.S. Cl. 257/637; 438/618; 438/613; 438/694; 257/E29.007; 257/E21.584; 257/E21.589; 257/E21.249

(57) ABSTRACT

A barrier layer deposited on the passivation layer of a semiconductor die decreases adhesion of glue used during stacking of semiconductor dies by altering chemical or structural properties of the passivation layer. During detachment of a carrier wafer from a wafer, the barrier layer reduces glue residue on the wafer by modifying the surface of the passivation layer. The barrier layer may be insulating films such as silicon dioxide, silicon nitride, silicon carbide, polytetrafluoroethylene, organic layers, or epoxy and may be less than two micrometers in thickness. Additionally, the barrier layer may be used to reduce topography of the semiconductor die to decrease adhesion of glues.

### TECHNICAL FIELD

The present disclosure generally relates to integrated circuits. More specifically, the present disclosure relates to packaging integrated circuits.

### BACKGROUND

Passivation of an integrated circuit (IC) during fabrication is conventionally accomplished by depositing a polymer such as polyimide over the IC. The passivation layer provides compliance and acts as a mechanical cushion for the IC. Polymers have several characteristics that may cause problems during later steps in packaging. For example, polymers have high moisture absorption rates, which reduce reliability of the IC after packaging. Additionally, polymers have strong adhesion to glues temporarily applied during packaging, which increases the difficulty of removing the glue. One example of when glues are applied is during manufacturing of stacked ICs.

Recently, desire for stacked ICs has increased as stacked ICs allow manufacturing of higher density ICs through 3D stacking than could be achieved on a 2D IC. For example, DRAM may be stacked above a microprocessor to increase the number of transistors and functionality of an IC without increasing the die size. A block diagram illustrating a conventional stacked IC is shown in FIG. 1A. A stacked IC 100 includes a packaging substrate 110. The packaging substrate 110 is coupled to a first tier die 120 through a packaging connection 112 such as bumps in a ball grid array. A second tier die 130 is coupled to the first tier die 120 through a packaging connection 122. The first tier die 120 includes through silicon vias 124, which couple the packaging substrate 110 to the packaging connection 122 to allow communication with the second tier die 130.

Manufacturing through silicon vias 124 in the first tier die 120 includes thinning the first tier die 120. To improve stability of the first tier die 120 during thinning, the first tier die 120 is attached to a carrier wafer by glue. A flow chart illustrating a conventional process flow for manufacturing a stacked IC is shown in FIG. 1B. At block 150 a wafer is received and attached to a carrier wafer at block 155. The wafer is thinned at block 160 and processed at block 165. Processing at block 165 may include, for example, attaching a second tier wafer. At block 170 the wafer is detached from the carrier wafer.

Glue applied during carrier wafer attachment at block 155 attaches to the final passivation layer of integrated circuits on the first tier wafer. Adhesion between glue and the final passivation layer causes difficulty in completely removing the glue during detachment from the carrier wafer at block 170. Additionally, plasma processing of the passivation layer roughens the passivation layer, further increasing adhesion. The adhesion problem is demonstrated with reference to FIGS. 2A-B.

FIG. 2A is a block diagram illustrating a conventional wafer attached to a carrier wafer. A carrier wafer 210 is attached to a wafer 222 by a glue 220. The wafer 222 includes a semiconductor layer 295. A flip chip bump 230 provides an electrical contact to a metal layer 260 (e.g., redistribution layer) and a top metal 262. Insulating layers 250, 270, 280 separate the metal layer 260 from other layers in the wafer 222. The insulating layer 280 may be, for example, a low-k (LK), an extra low-k (ELK), or an ultra low-k (ULK) dielectric layer. A passivation layer 240 on the wafer 222 provides the final separation between outside elements and the wafer 222. Adhesion between the glue 220 and the passivation layer 240 makes removal of the glue 220 after detachment of the carrier wafer 210 difficult as illustrated in FIG. 2B.

FIG. 2B is a block diagram illustrating a conventional wafer after detachment from a carrier wafer. The carrier wafer 210 is detached from the glue 220, and the glue 220 is removed from wafer 222. However, strong adhesion between the glue 220 and the passivation layer 240 results in residue left behind. Additionally, strong adhesion results in delamination 282 of the LK, ELK, and/or ULK dielectrics in the insulating layer 280. Reduced mass of LK, ELK, and ULK dielectric materials increases susceptibility of the insulating layer 280 to delamination 282. Damage to the insulating layer 280 may change operating characteristics of ICs in the wafer 222.

Thus, there is a need for an improved process and structure for passivation of integrated circuits.

### BRIEF SUMMARY

According to one aspect of the disclosure, a layer structure for a semiconductor die includes an insulating layer of the semiconductor die. The layer structure also includes a passivation layer on the insulating layer that provides compliance for the semiconductor die. The layer structure further includes a barrier layer on the passivation layer that reduces adhesion of glues applied during semiconductor manufacturing to the passivation layer.

According to another aspect of the disclosure, a semiconductor manufacturing process includes patterning a passivation layer of a semiconductor die. The semiconductor manufacturing process also includes depositing a barrier layer on the passivation layer that reduces adhesion of glues applied during the semiconductor manufacturing process to the passivation layer. The semiconductor manufacturing process further includes patterning the barrier layer.

According to yet another aspect of the disclosure, a semiconductor manufacturing process includes building up a flip chip bump. The semiconductor manufacturing process also includes depositing a barrier layer after building up the flip chip bump. The semiconductor manufacturing process further includes patterning the barrier layer to expose the flip chip bump.

According to another aspect of the disclosure, a layer structure for a semiconductor die includes an insulator layer of the semiconductor die. The layer structure also includes a passivation layer on the insulator layer. The layer structure further includes means for modifying a surface to decrease adhesion, the surface modifying means disposed on the passivation layer.

According to yet another aspect of the disclosure, a semiconductor manufacturing process includes depositing a barrier layer on a semiconductor die to substantially cover an interface structure of the semiconductor die and to substantially cover a passivation layer of the semiconductor die. The semiconductor manufacturing process also includes etching the barrier layer to create a surface having reduced topography.

According to a further aspect of the disclosure, a semiconductor manufacturing process includes patterning a passivation layer of a semiconductor die. The semiconductor manufacturing process also includes depositing a barrier layer on the passivation layer that reduces adhesion of glues applied during the semiconductor manufacturing process to the passivation layer. The semiconductor manufacturing process further includes patterning the barrier layer.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the technology of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following description taken in conjunction with the accompanying drawings.

FIG. 1A is a block diagram illustrating a conventional stacked IC.

FIG. 1B is a flow chart illustrating a conventional process flow for manufacturing a stacked IC.

FIG. 2A is a block diagram illustrating a conventional wafer attached to a carrier wafer.

FIG. 2B is a block diagram illustrating a conventional wafer after detachment from a carrier wafer.

FIG. 3A is a block diagram illustrating a wafer having an exemplary barrier layer attached to a carrier wafer according to one embodiment.

FIG. 3B is a block diagram illustrating a wafer having an exemplary barrier layer after detachment from a carrier wafer according to one embodiment.

FIG. 4 is a flow chart illustrating an exemplary process flow for forming the barrier layer according to a first embodiment.

FIGS. 5A-F are block diagrams illustrating a die during an exemplary process for forming the barrier layer according to the first embodiment.

FIG. 6 is a flow chart illustrating an exemplary process flow for forming the barrier layer according to a second embodiment.

FIGS. 7A-F are block diagrams illustrating a die during an exemplary process for forming the barrier layer according to the second embodiment.

FIG. 8 is a block diagram illustrating an exemplary stacked IC having a barrier layer according to one embodiment.

FIGS. 9A-C are cross-sectional views illustrating a die during an exemplary process for forming the barrier layer according to a third embodiment.

FIG. 10 is a flow chart illustrating an exemplary process flow for forming the barrier layer according to the third embodiment.

FIG. 11 is a block diagram showing an exemplary wireless communication system in which an embodiment may be advantageously employed.

FIG. 12 is a block diagram illustrating a design workstation used for circuit, layout, and logic design of a semiconductor component according to one embodiment.

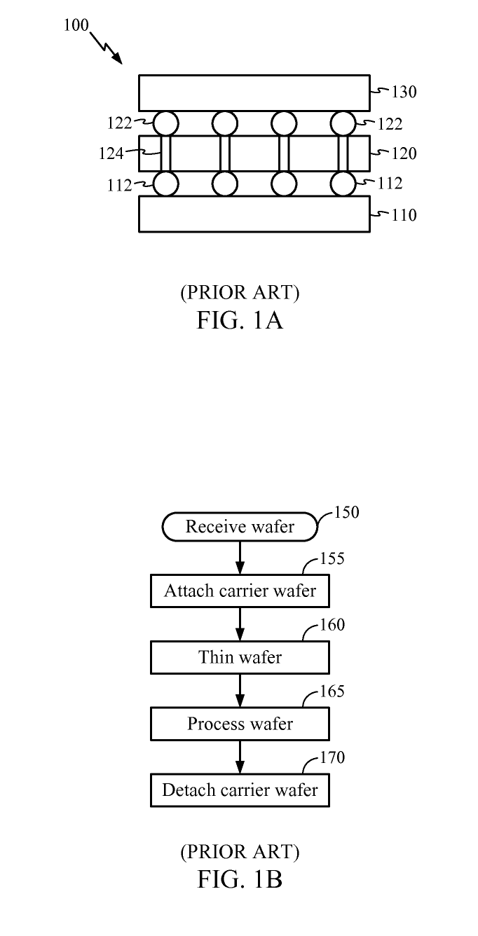

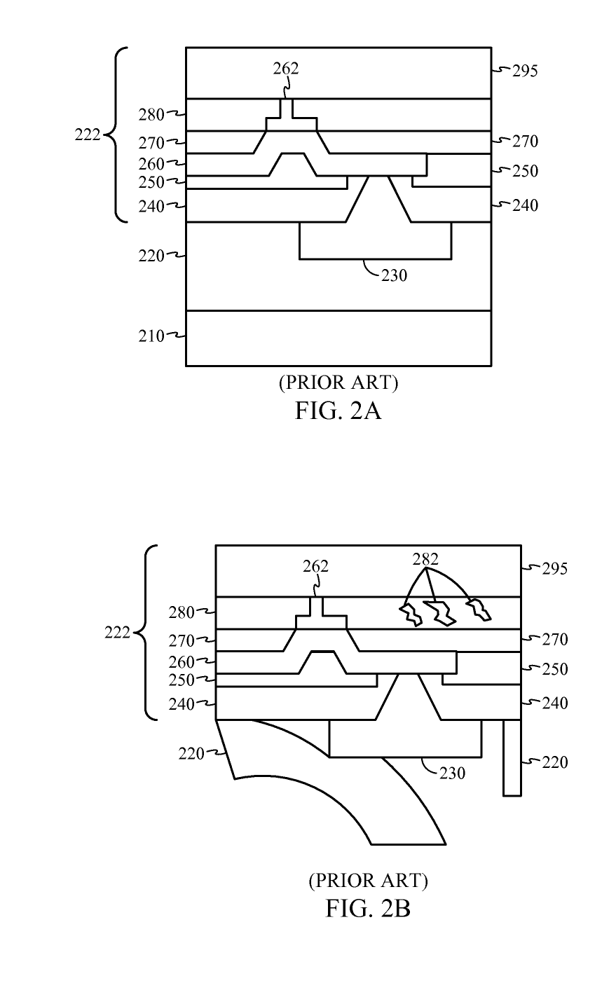

### DETAILED DESCRIPTION

A barrier layer may be deposited on the passivation layer of an integrated circuit (IC) to improve detachment of the carrier wafer after wafer thinning and to reduce glue residue remaining on the wafer after detachment. The barrier may be, for example, an inorganic film such as silicon nitride, silicon oxide, or an organic material such as polytetrafluoroethylene. The barrier layer may alter either the chemical or structural properties of the passivation layer to reduce adhesion.

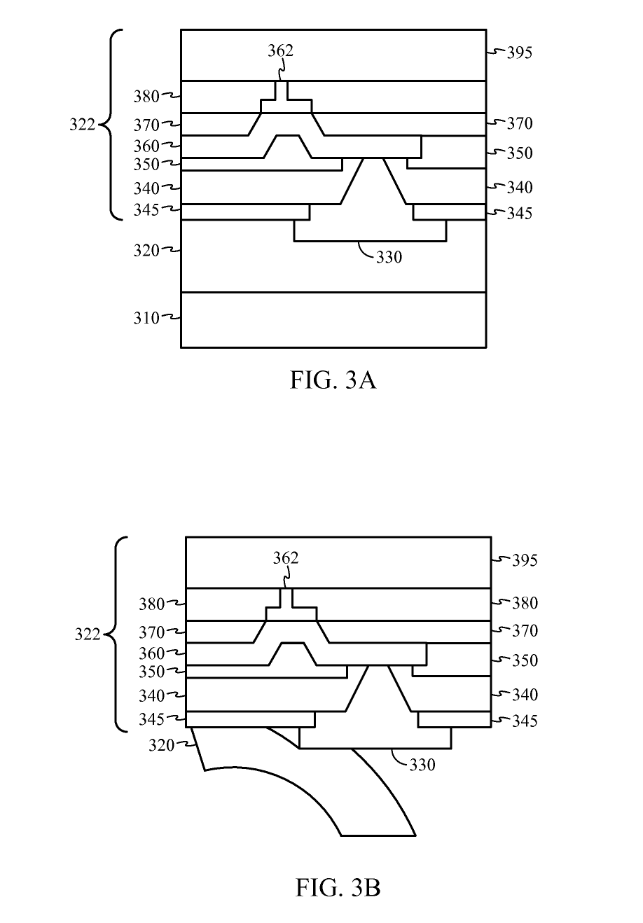

FIG. 3A is a block diagram illustrating a wafer having an exemplary barrier layer attached to a carrier wafer according to one embodiment. A carrier wafer 310 is attached to a wafer 322 by a glue 320. The wafer 322 includes semiconductor layer 395 which may have front end of line (FEOL) layers and low metal layers. A bump 330 provides connection to a metal layer 360 such as, for example, a redistribution layer. The metal layer 360 couples to a top metal 362 for communication with devices and/or back-end-of-line (BEOL) layers in a semiconductor layer 395. The wafer 322 also includes insulating layers 350, 370, 380. A passivation layer 340 deposited on the wafer 322 protects the wafer 322 from outside elements and provides compliance.

Additionally, a barrier layer 345 deposited on the passivation layer 340 reduces adhesion between the glue 320 and the passivation layer 340. The barrier layer 345 modifies the surface of the passivation layer 340 to reduce moisture absorption and decrease adhesion to the glue 320. That is, the barrier layer 345 alters the chemical properties of the passivation layer 340. Stress and thickness of the barrier layer 345 are selected to preserve the low stress of the passivation layer 340. According to one embodiment, the barrier layer 345 is less than two micrometers in thickness and is either silicon dioxide, silicon nitride, silicon carbide, aluminum oxide, polytetrafluoroethylene, or other insulating materials. According to another embodiment, the thickness of the barrier layer 345 is 0.05-1.0 micrometers.

FIG. 3B is a block diagram illustrating a wafer having an exemplary barrier layer after detachment from a carrier wafer according to one embodiment. After detaching the carrier wafer 310, the glue 320 is removed. The barrier layer 345 decreases adhesion of the glue 320 to the passivation layer 340 allowing removal of the glue 320 with reduced residue remaining on the wafer 322.

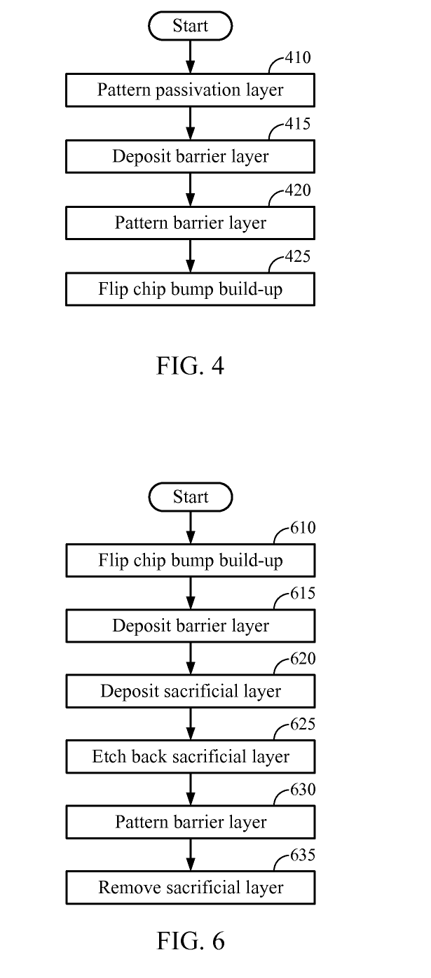

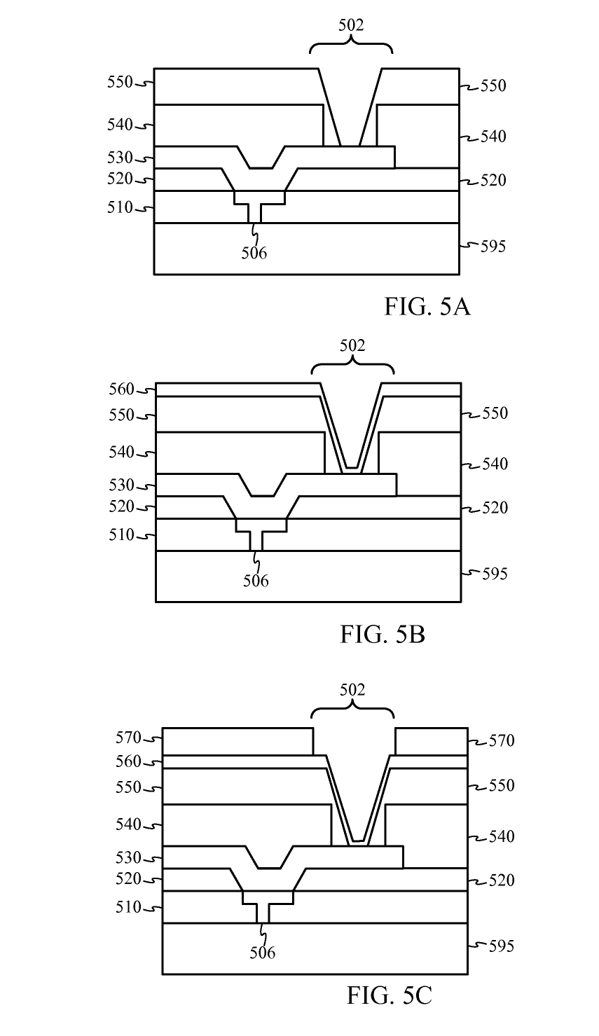

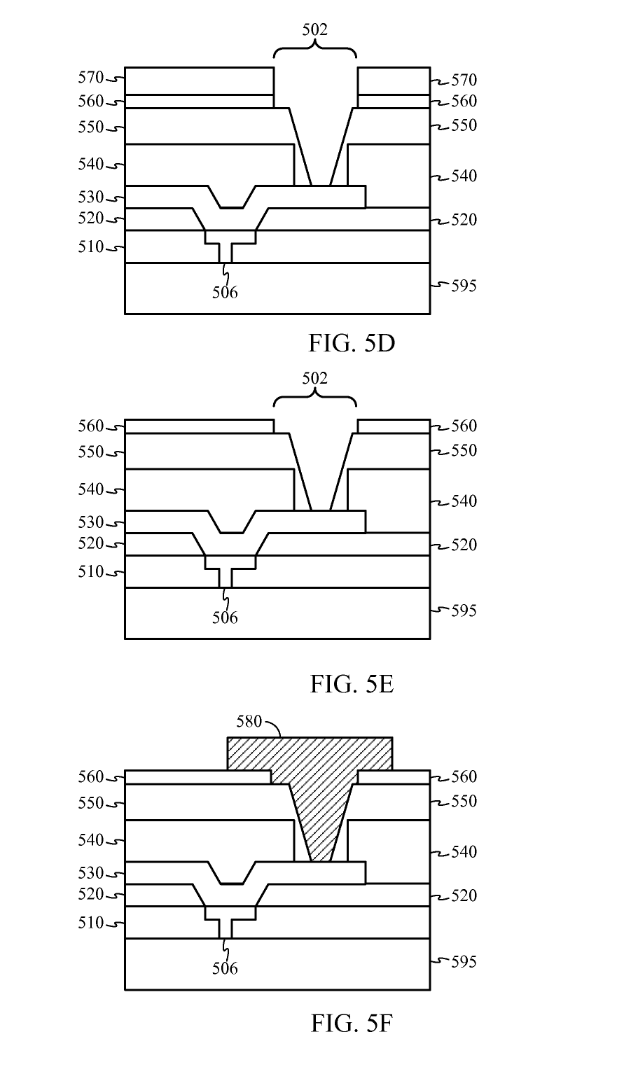

A process for depositing the barrier layer on the passivation layer is illustrated with reference to FIG. 4 and FIGS. 5A-F. FIG. 4 is a flow chart illustrating an exemplary process flow for forming the barrier layer according to a first embodiment. At block 410 a passivation layer is patterned. FIG. 5A is a block diagram illustrating a wafer after patterning of the passivation layer according to the first embodiment. Insulating layers 510, 520, 540 surround a metal layer 530. According to one embodiment, the insulating layer 510 is SiO₂, fluorosilicate glass (FSG), LK, ELK, or ULK, the insulating layer 520 is silicon dioxide or fluorine doped silicon dioxide, and the insulating layer 540 is silicon dioxide or silicon nitride. The metal layer 530 couples through a top metal 506 to, for example, devices and back-end-of-line (BEOL) layers on a semiconductor layer 595. A passivation layer 550 on the insulating layer 540 is patterned to create an opening 502. The opening 502 may be formed by, for example, depositing a photoresist layer (not shown), patterning the photoresist layer, wet or dry etching the passivation layer 550, and stripping the photoresist layer.

At block 415 a barrier layer is deposited. FIG. 5B is a block diagram illustrating a wafer after deposition of a barrier layer according to the first embodiment. A barrier layer 560 is deposited on the passivation layer 550 and may be, for example, silicon dioxide, silicon nitride, silicon carbide, aluminum oxide, polytetrafluoroethylene, or other insulating materials. According to one embodiment, the barrier layer 560 is less than two micrometers in thickness.

At block 420 the barrier layer is patterned. The barrier layer may be patterned, for example, using a photoresist as a hard mark for etching. FIG. 5C is a block diagram illustrating a wafer after deposition of a photoresist according to the first embodiment. A photoresist 570 is deposited on the barrier layer 560 and patterned to substantially align with the opening 502.

FIG. 5D is a block diagram illustrating a wafer after etching of the barrier layer according to the first embodiment. A photoresist 570 acts as a hard mask during etching of the barrier layer 560 from the opening 502. The barrier layer 560 may be etched, for example, by wet or dry etching processes.

FIG. 5E is a block diagram illustrating a wafer after stripping the photoresist according to the first embodiment. After etching the barrier layer 560 from the opening 502, the photoresist 570 is stripped from the remainder of the barrier layer 560.

At block 425 flip chip build up occurs to connect with the top metal layer. FIG. 5F is a block diagram illustrating a wafer after flip chip build up according to the first embodiment. A bump 580 is deposited in the opening 502 for external connections to the metal layer 530. For example, the bump 580 may be used to couple external components to the metal layer 530.

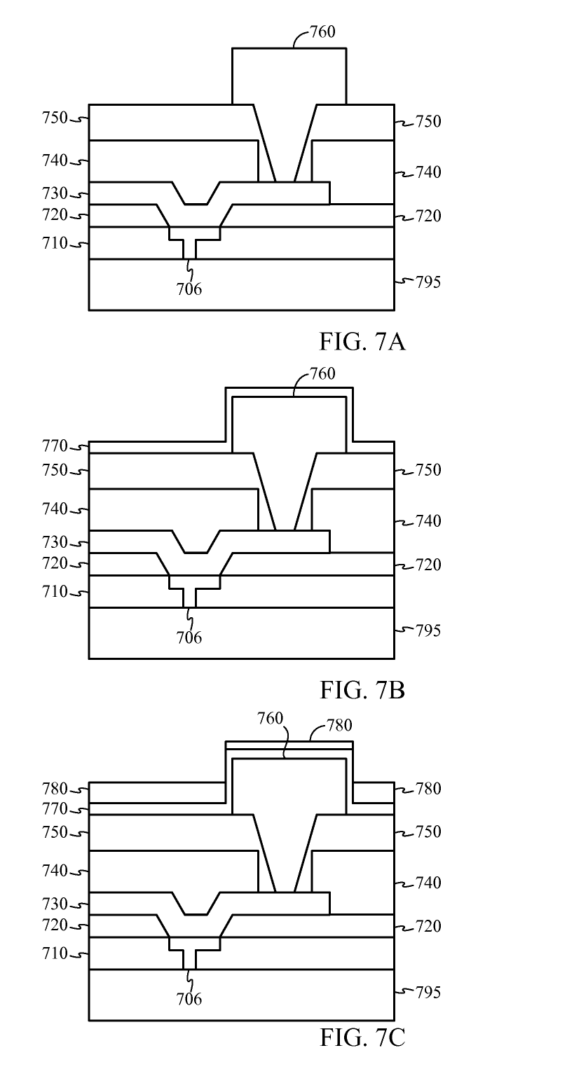

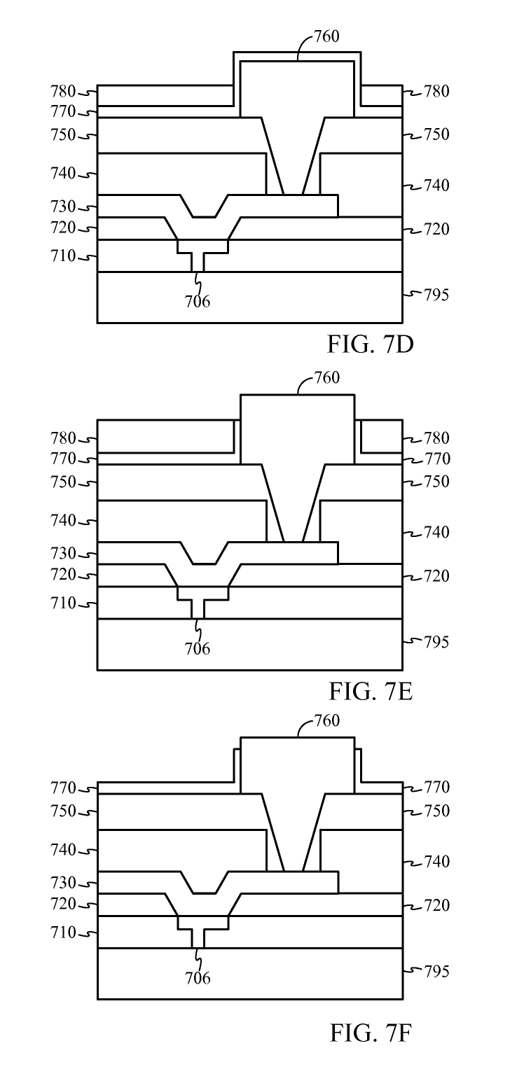

An alternative process flow for depositing the passivation layer is illustrated with reference to FIG. 6 and FIGS. 7A-F. FIG. 6 is a flow chart illustrating an exemplary process flow for forming the barrier layer according to a second embodiment. At block 610 flip chip bump build up occurs. FIG. 7A is a block diagram illustrating a wafer after flip chip bump build up according to the second embodiment. Insulating layers 710, 720, 740 surround a metal layer 730. A top metal 706 couples to the metal layer 730 to provide communication to, for example, vias, other metal layers and devices on a semiconductor layer 795. A passivation layer 750 on the insulating layer 740 provides compliance and may be, for example, polyimide or another polymer. A bump 760 connects through the passivation layer 750 to the metal layer 730 for coupling external components to the top metal 706. An under bump metallurgy (UBM) (not shown) may be deposited before the bump 760 to facilitate building of the bump 760.

At block 615 a barrier layer is deposited. FIG. 7B is a block diagram illustrating a wafer after deposition of a barrier layer according to the second embodiment. A barrier layer 770 is deposited on the passivation layer 750 and the bump 760. The barrier layer 770 may be, for example, silicon dioxide, silicon nitride, silicon carbide, aluminum oxide, polytetrafluoroethylene, or other insulating materials. According to one embodiment, the barrier layer 770 is less than two micrometers in thickness.

At block 620 a sacrificial layer is deposited. FIG. 7C is a block diagram illustrating a wafer after deposition of a sacrificial layer according to the second embodiment. A sacrificial layer 780, such as a photoresist, is deposited on the barrier layer 770. The sacrificial layer 780 may be spray coated such that the thickness of the sacrificial layer 780 on the bump 760 is thinner than the thickness of the sacrificial layer 780 is other regions.

At block 625 the sacrificial layer is etched back. FIG. 7D is a block diagram illustrating a wafer after etch back of the sacrificial layer according to the second embodiment. The sacrificial layer 780 is etched back by, for example, wet or dry etching. After etch back, the barrier layer 770 is exposed on the bump 760. The sacrificial layer 780 remains in regions around the bump 760 because of a greater thickness.

At block 630 the barrier layer is patterned. FIG. 7E is a block diagram illustrating a wafer after patterning of the barrier layer according to the second embodiment. The barrier layer 770 is patterned using, for example, dry or wet etch processes with the sacrificial layer 780 acting as a hard mask. In regions where the sacrificial layer 780 remains intact, the barrier layer 770 is left relatively unchanged. In regions where the sacrificial layer 780 was removed, the barrier layer 770 is etched away to expose the bump 760.

At block 635 the sacrificial layer is removed. FIG. 7F is a block diagram illustrating a wafer after removal of the sacrificial layer according to the second embodiment. The sacrificial layer 780 is removed through, for example, wet or dry etch processes exposing the barrier layer 770. Substantially all of the passivation layer 750 is covered by the barrier layer 770. Thus, any glue attached to the passivation layer 750 is easier to remove due to modifications to the surface of the passivation layer 750 by the barrier layer 770, resulting in reduced adhesion.

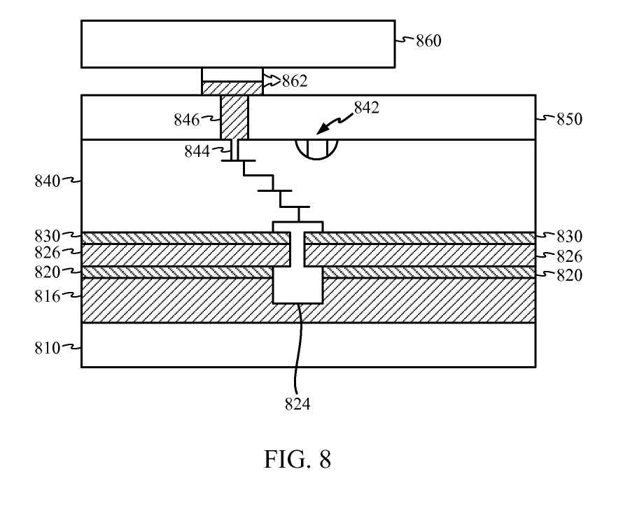

A barrier layer as described above may be implemented in construction of a stacked IC. FIG. 8 is a block diagram illustrating an exemplary stacked IC having a barrier layer according to one embodiment. A first tier die 850 is coupled to a second tier die 860 through an interconnect 862. Devices in the first tier die 850 include, for example, a transistor 842. The interconnect 862 couples to a through silicon via 846 in the first tier die 850 and interconnects 844. The interconnects 844 are surrounded by an insulating layer 840 such as, for example, LK, HLK, or ULK dielectrics. The interconnects 844 couple to a bump 824 to allow communication between the first tier die 850, the second tier die 860, and external components.

Deposited on the insulating layer 840 is a first passivation layer 830 and a second passivation layer 826. According to one embodiment, the first passivation layer 830 is silicon nitride, and the second passivation layer 826 is polyimide. A barrier layer 820 covers substantially all of the second passivation layer 826 to reduce residue left by a glue 816 after detachment of a carrier wafer 810. The carrier wafer 810 provides support for the first tier die 850 during processing, such as thinning the first tier die 850, to reduce fragility of the first tier die 850.

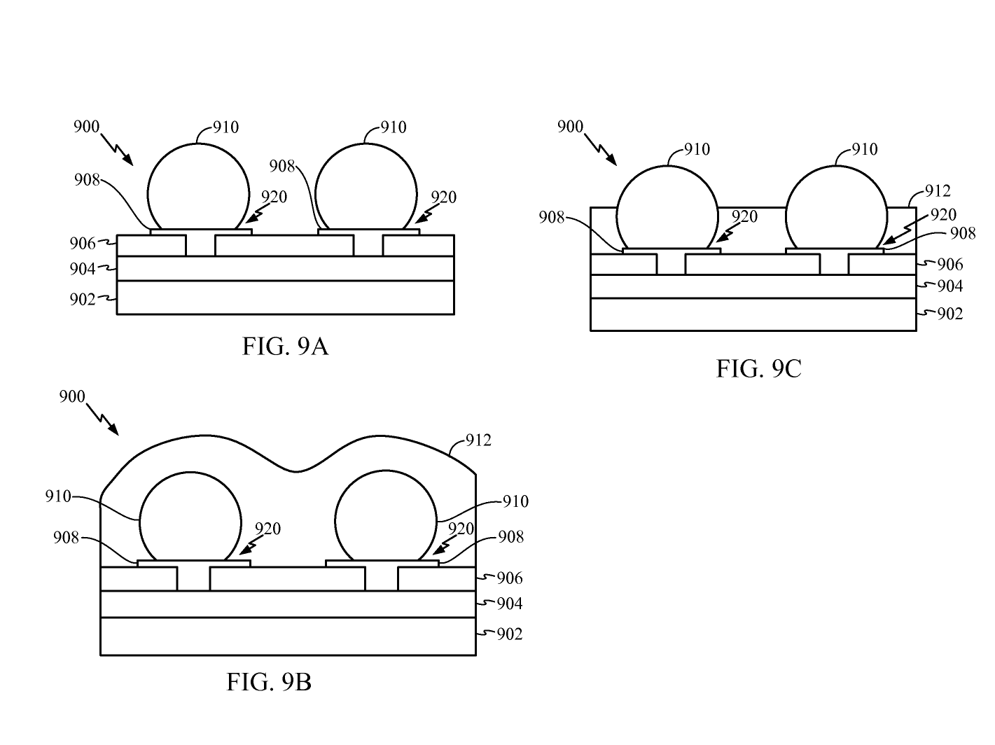

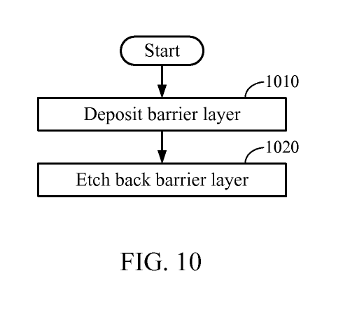

According to a third embodiment, a barrier layer is deposited and etched to reduce topography of a layer structure of a semiconductor wafer to reduce glue adhesion. Glue adhesion may be reduced through altering of structural properties. FIGS. 9A-9C are cross-sectional views illustrating barrier layer deposition and etching according to the third embodiment. FIG. 10 is a flow chart illustrating an exemplary process flow for forming the barrier layer according to the third embodiment.

Referring to FIG. 9A, film layers 904 of a layer structure 900 are located on a semiconductor layer 902. The film layers may include metal layers, top metal interconnects, insulating layers, vias, and passivation layers. On the film layers 904 is a passivation layer 906. Under bump metallurgy (UBM) 908 on the passivation layer 906 couples an interface structure 910 (e.g., bumps) to devices (not shown) on the semiconductor layer 902 through vias and metal layers in the film layers 904. Large topography differences (e.g., height variation between the top of the bump 910 and a surface of the passivation layer 906) and access to locking regions 920 allow adhesives (not shown) deposited on the layer structure 900 to lock into the layer structure 900 increasing difficulty of removing the adhesive.

At block 1010 a barrier layer 912 is deposited on the layer structure 900 to substantially cover the bumps 910 and the passivation layer 906 as shown in FIG. 9B. The barrier layer 912 may be, for example, silicon nitride, an organic film, or an epoxy.

At block 1020, the barrier layer 912 is etched back as shown in FIG. 9C. The etching may include a photoresist deposition and patterning process. The barrier layer 912 is etched back and results in a reduced topography and reduced exposure of locking regions 920 of the layer structure 900. After etching, the barrier layer 912 has a substantially flat surface. The reduced topography prevents an adhesive deposited on the layer structure 900 from locking into the bumps 910. That is, adhesion is reduced through altering of structural properties of the layer structure 900.

The layer structure 900 of FIG. 9C may be stacked with other semiconductor wafers by depositing an adhesive, attaching a carrier wafer, thinning the layer structure 900, processing the layer structure 900, attaching a second tier die, and detaching the carrier wafer by dissolving the adhesive. The barrier layer 912 reduces adhesion of the adhesive layer to the layer structure 900 allowing removal of the adhesive without any residue remaining on the layer structure 900. The barrier layer 912 may be removed through wet and/or dry etching after the adhesive is dissolved.

According to one embodiment, an additional barrier layer (not shown) may be deposited between the barrier layer 912 and the passivation layer 906. The additional barrier layer may be deposited according to the first and/or second embodiments described above.

A barrier layer deposited over a passivation layer decreases residue of glues attached to the passivation layer by decreasing adhesion of glue to the passivation layer. Inorganic materials may be chosen for the barrier layer because inorganic materials have increased resistance to plasma and chemical processes, which increase surface roughness of other materials. Decreased surface roughness further reduces adhesion of glues to the passivation layer. The barrier layer is used in one embodiment during construction of stacked ICs to reduce glue residue remaining after detachment of a carrier wafer.

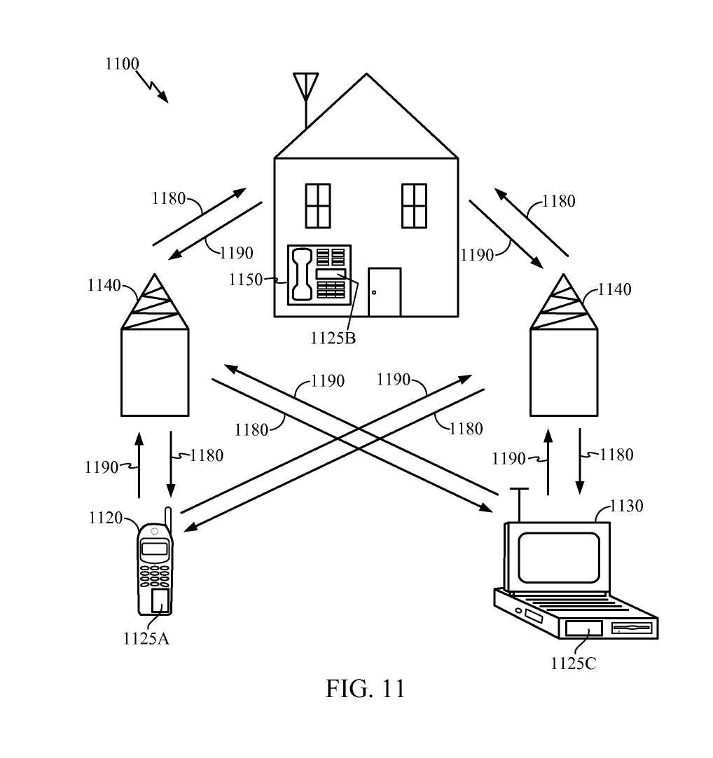

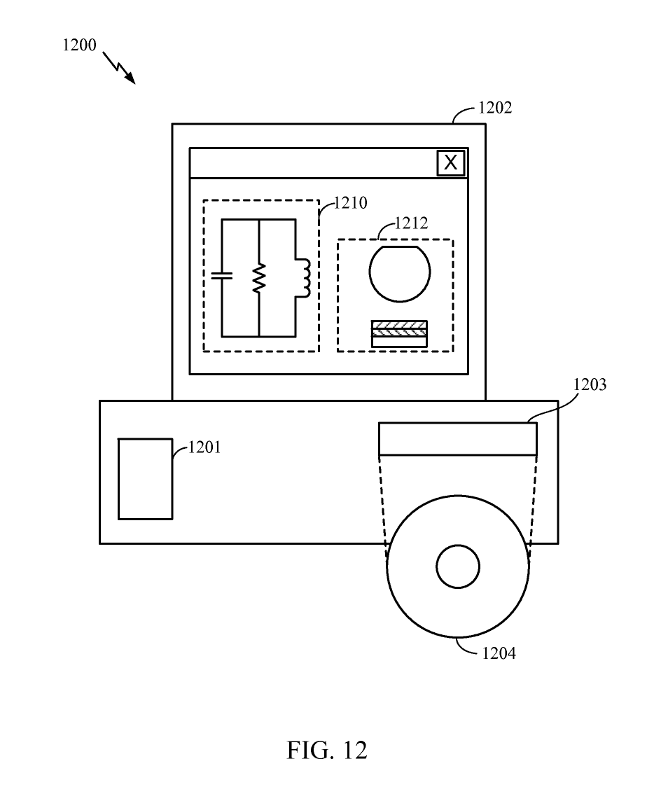

FIG. 11 shows an exemplary wireless communication system 1100 in which an embodiment of the disclosure may be advantageously employed. For purposes of illustration, FIG. 11 shows three remote units 1120, 1130, and 1150 and two base stations 1140. It will be recognized that wireless communication systems may have many more remote units and base stations. Remote units 1120, 1130, and 1150 include improved packaged ICs 1125A, 1125C, and 1125B, respectively, which are embodiments as discussed above. FIG. 10 shows forward link signals 1180 from the base stations 1140 and the remote units 1120, 1130, and 1150 and reverse link signals 1190 from the remote units 1120, 1130, and 1150 to base stations 1140.

In FIG. 11, remote unit 1120 is shown as a mobile telephone, remote unit 1130 is shown as a portable computer, and remote unit 1150 is shown as a computer in a wireless local loop system. For example, the remote units may be cell phones, hand-held personal communication systems (PCS) units, portable data units such as personal data assistants, fixed location data units such as meter reading equipment, set top boxes, music players, video players, entertainment units, navigation devices, or computers. Although FIG. 11 illustrates remote units according to the teachings of the disclosure, the disclosure is not limited to these exemplary illustrated units. The disclosure may be suitably employed in any device which includes packaged ICs.

FIG. 12 is a block diagram illustrating a design workstation used for circuit, layout, and logic design of a semiconductor component as disclosed below. A design workstation 1200 includes a hard disk 1201 containing operating system software, support files, and design software such as Cadence or OrCAD. The design workstation 1200 also includes a display to facilitate design of a circuit 1210 or a semiconductor component 1212 such as a wafer or die. A storage medium 1204 is provided for tangibly storing the circuit design 1210 or the semiconductor component 1212. The circuit design 1210 or the semiconductor component 1212 may be stored on the storage medium 1204 in a file format such as GDSII or GERBER. The storage medium 1204 may be a CD-ROM, DVD, hard disk, flash memory, or other appropriate device. Furthermore, the design workstation 1200 includes a drive apparatus 1203 for accepting input from or writing output to the storage medium 1204.

Data recorded on the storage medium 1204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1204 facilitates the design of the circuit design 1210 or the semiconductor component 1212 by decreasing the number of processes for designing semiconductor wafers.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the terminology “through silicon via” includes the word silicon, it is noted that through silicon vias are not necessarily constructed in silicon. Rather, the material can be any device substrate material.

Although the present invention and its advantages have been described in detail, it should be understood that various changes, substitutions and alterations can be made herein without departing from the technology of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A layer structure for a semiconductor die, comprising:
an insulating layer of the semiconductor die;
a passivation layer on the insulating layer that provides compliance for the semiconductor die; and
a barrier layer on the passivation layer that reduces adhesion of glues applied during semiconductor manufacturing to the passivation layer.

2. The layer structure of claim 1, in which the barrier layer is at least one of silicon dioxide, silicon nitride, silicon carbide, polytetrafluoroethylene, organic materials, and epoxy.

3. The layer structure of claim 1, in which the barrier layer modifies chemical properties of the passivation layer to reduce adhesion.

4. The layer structure of claim 1, in which the barrier layer modifies structural properties of the passivation layer

5. The layer structure of claim 1, integrated into a stacked integrated circuit.

6. The layer structure of claim 1, integrated into at least one of a mobile phone, a set top box, a music player, a video player, an entertainment unit, a navigation device, a computer, a hand-held personal communication systems (PCS) unit, a portable data unit, and a fixed location data unit.

7. A semiconductor manufacturing process, comprising:
patterning a passivation layer of a semiconductor die;
depositing a barrier layer on the passivation layer that reduces adhesion of glues applied during the semiconductor manufacturing process to the passivation layer; and
patterning the barrier layer.

8. The semiconductor manufacturing process of claim 7, further comprising building up an interconnect after patterning the barrier layer.

9. The semiconductor manufacturing process of claim 7, in which depositing the barrier layer comprises depositing at least one of silicon dioxide, silicon nitride, silicon carbide, and polytetrafluoroethylene.

10. The semiconductor manufacturing process of claim 7, in which depositing the barrier layer comprises depositing less than two micrometers of the barrier layer.

11. The semiconductor manufacturing process of claim 7, in which patterning the barrier layer comprises:
depositing a photoresist;
patterning the photoresist;
etching the barrier layer after patterning the photoresist; and
removing the photoresist after etching the barrier layer.

12. The semiconductor manufacturing process of claim 7, in which the semiconductor manufacturing process is integrated into the manufacturing of stacked integrated circuits.

13. A semiconductor manufacturing process, comprising:
building up a flip chip bump;
depositing a barrier layer after building up the flip chip bump; and
patterning the barrier layer to expose the flip chip bump.

14. The semiconductor manufacturing process of claim 13, in which patterning the barrier layer comprises:
depositing a sacrificial layer;
etching back the sacrificial layer;
etching the barrier layer after etching back the sacrificial layer; and
removing the sacrificial layer after etching the barrier layer.

15. The semiconductor manufacturing process of claim 13, in which depositing the barrier layer comprises depositing at least one of silicon dioxide, silicon nitride, silicon carbide, and polytetrafluoroethylene.

16. The semiconductor manufacturing process of claim 13, in which depositing the barrier layer comprises depositing less than two micrometers of the barrier layer.

17. A layer structure for a semiconductor die, comprising:
an insulator layer of the semiconductor die;
a passivation layer on the insulator layer; and
means for modifying a surface to decrease adhesion, the surface modifying means disposed on the passivation layer.

18. The layer structure of claim 17, in which the surface modifying means comprises means for altering structural properties of the passivation layer.

19. The layer structure of claim 17, in which the surface modifying means comprises means for altering chemical properties of the passivation layer.

20. The layer structure of claim 17, further comprising an integrated circuit, the insulator layer disposed on the integrated circuit.

21. The layer structure of claim 20, integrated into at least one of a mobile phone, a set top box, a music player, a video player, an entertainment unit, a navigation device, a computer, a hand-held personal communication systems (PCS) unit, a portable data unit, and a fixed location data unit.

22. A semiconductor manufacturing process, comprising:
depositing a barrier layer on a semiconductor die to substantially cover an interface structure of the semiconductor die and to substantially cover a passivation layer of the semiconductor die; and
etching the barrier layer to create a surface having reduced topography.

23. The semiconductor manufacturing process of claim 22, further comprising integrated the semiconductor die into the manufacturing of stacked integrated circuits.

24. A semiconductor manufacturing process, comprising the steps of:
patterning a passivation layer of a semiconductor die;
depositing a barrier layer on the passivation layer that reduces adhesion of glues applied during the semiconductor manufacturing process to the passivation layer; and
patterning the barrier layer.

25. The semiconductor manufacturing process of claim 24, further comprising integrated the semiconductor die into the manufacturing of stacked integrated circuits.
